(19) United States
(12) Patent Application Publication
(10) Pub. No.: US 2024/0171131 A1
(43) Pub. Date: May 23, 2024

(54) Level-shifting amplifier with gain error reduction

(71) Applicant: National Cheng Kung University, Tainan City (TW)

(72) Inventors: Jia-Ching Wang, Taipei City (TW); Tai-Haur Kuo, Tainan City (TW)

(73) Assignee: National Cheng Kung University, TAINAN CITY (TW)

(21) Appl. No.: 17/991,809

(22) Filed: Nov. 21, 2022

(51) Int. Cl. H03F 1/32

(52) U.S. Cl. CPC H03F 1/3247

(57) ABSTRACT

An amplifier circuit includes an input terminal, configured to receive an input voltage; an output terminal, configured to output an output voltage; a multi-stage operational amplifier, coupled to the input terminal and the output terminal, and configured to amplify the input voltage to the output voltage, comprising a plurality of amplifiers; and a plurality of level-shifting networks, each coupled between two of the plurality of amplifiers, configured to reduce a gain error of each output of the plurality of amplifiers; and a feedback capacitor, coupled between the input terminal and the output terminal.

### BACKGROUND OF THE INVENTION

### 1. Field of the Invention

The present invention relates to an amplifier circuit, and more particularly, to an amplifier circuit with a plurality of level-shifting networks.

### 2. Description of the Prior Art

An amplifier with a wide bandwidth as well as a low gain error may be applied to an analog front-end circuitry to obtain a high signal-to-noise-and-distortion ratio (SNDR). In general, in order to reduce the gain error, an open-loop gain of the amplifier may be increased by implementing the amplifier utilizing a cascade topology or a cascode topology. However, the bandwidth and the power efficiency of the amplifier decrease as the open-loop gain increases.

For example, please refer to FIG. 1A. FIG. 1A is a schematic diagram of an amplifier circuit 1 in a multi-stage structure. The amplifier circuit 1 includes an input terminal T_{IN}, an output terminal T_{OUT}, a three-stages operational amplifier 10, and a feedback capacitor C_{F}. The input terminal T_{IN} is configured to receive an input voltage V_{IN}, the output terminal T_{OUT} is configured to output an output voltage V_{OUT}, and the three-stages operational amplifier 10 is configured to amplify the input voltage V_{IN} to the output voltage V_{OUT}. Please refer to FIG. 1B. FIG. 1B is a waveform diagram of the output voltage V_{OUT}. The open-loop gain (A1*A2*A3) of the three-stages operational amplifier 10 is finite and may cause a gain error, so that the output voltage V_{OUT} is less than an ideal voltage V_{IDEAL} by a gain error voltage V_{GE}. Therefore, how to improve the amplifier circuit 1 to have a wide bandwidth and a low gain error has become one of the goals in the industry.

### SUMMARY OF THE INVENTION

The present invention is to provide an amplifier circuit with a wide bandwidth and a low gain error.

The present invention provides an amplifier circuit, comprising an input terminal, configured to receive an input voltage; an output terminal, configured to output an output voltage; a multi-stage operational amplifier, coupled to the input terminal and the output terminal, and configured to amplify the input voltage to the output voltage, comprising a plurality of amplifiers; and a plurality of level-shifting networks, each coupled between two of the plurality of amplifiers, configured to reduce a gain error of each output of the plurality of amplifiers; and a feedback capacitor, coupled between the input terminal and the output terminal.

The present invention further provides an amplifier circuit, comprising an input terminal, configured to receive an input voltage; an output terminal, configured to output an output voltage; a first-stage operational amplifier, comprising a first input terminal, coupled to the input terminal, and a first output terminal, configured to amplify the input voltage to a first output voltage; a first level-shifting network, coupled to the first output terminal, configured to shift a level of the first output voltage to a first level-shifting voltage; a second-stage operational amplifier, comprising a second input terminal, coupled to the first level-shifting network, and a second output terminal, configured to amplify the first level-shifting voltage to a second output voltage; a second level-shifting network, coupled to the second output terminal, configured to shift a level of the second output voltage to a second level-shifting voltage; a third-stage operational amplifier, comprising a third input terminal, coupled to the second level-shifting network, and a third output terminal coupled to the output terminal, configured to amplify the second level-shifting voltage to the output voltage; a feedback capacitor, coupled between the input terminal and the output terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of an amplifier circuit in a multi-stage structure.

FIG. 1B is a waveform diagram of an output voltage of the amplifier circuit shown in FIG. 1A.

FIG. 2 is a schematic diagram of an amplifier circuit according to an embodiment of the present invention.

FIG. 3 is a schematic diagram of a plurality of level-shifting networks according to an embodiment of the present invention.

FIG. 4 is a waveform diagram of control signals of a plurality of switched-capacitor circuits according to an embodiment of the present invention.

FIG. 5 is a waveform diagram of an output voltage of the amplifier circuit shown in FIG. 2 according to an embodiment of the present invention.

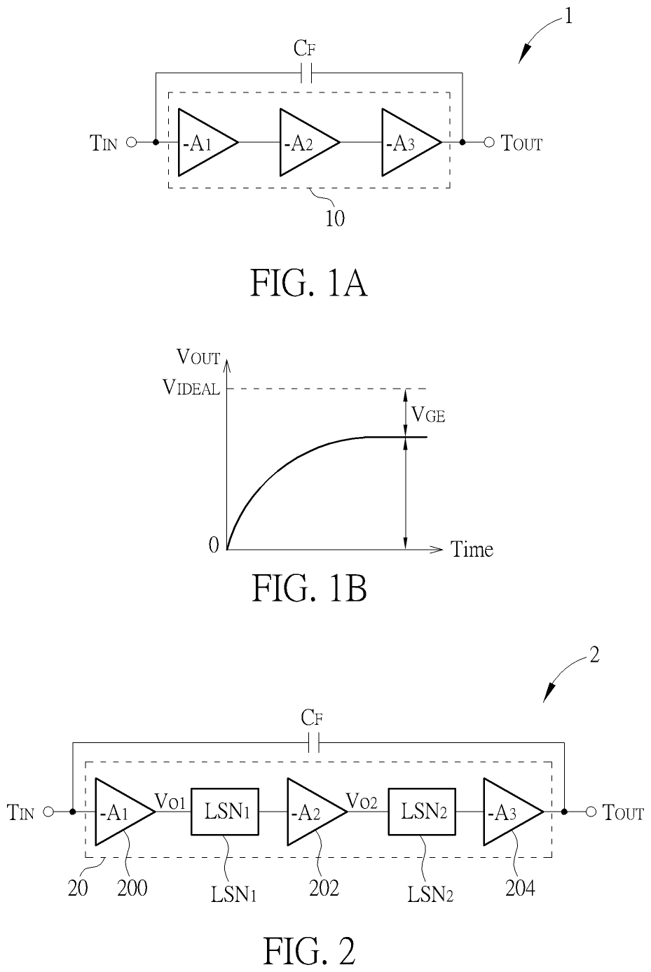

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

Please refer to FIG. 2. FIG. 2 is a schematic diagram of an amplifier circuit 2 according to an embodiment of the present invention. The amplifier circuit 2 includes an input terminal T_{IN}, an output terminal T_{OUT}, a multi-stage operational amplifier 20, and a feedback capacitor C_{F}. The input terminal T_{IN} is configured to receive an input voltage V_{IN}. The output terminal T_{OUT} is configured to output an output voltage V_{OUT}. The multi-stage operational amplifier 20 and the feedback capacitor C_{F} are coupled between the input terminal T_{IN} and the output terminal T_{OUT} and configured to amplify the input voltage V_{IN} to the output voltage V_{OUT}. In detail, the multi-stage operational amplifier 20 includes a plurality of amplifiers (e.g. 200, 202 and 204 in FIG. 2) and a plurality of level-shifting networks (e.g. LSN1 and LSN2 in FIG. 2). Each level-shifting network is coupled between two of the plurality of amplifiers and configured to reduce a gain error of each output of the plurality of amplifiers. It should be noted that, a number of the plurality of amplifiers is greater than or equal to 3 and a number of the plurality of level-shifting networks is greater than or equal to 2. For example, as shown in FIG. 2, the level-shifting network LSN1 is coupled between the amplifier 200 and the amplifier 202, and the level-shifting network LSN2 is coupled between the amplifier 202 and the amplifier 204.

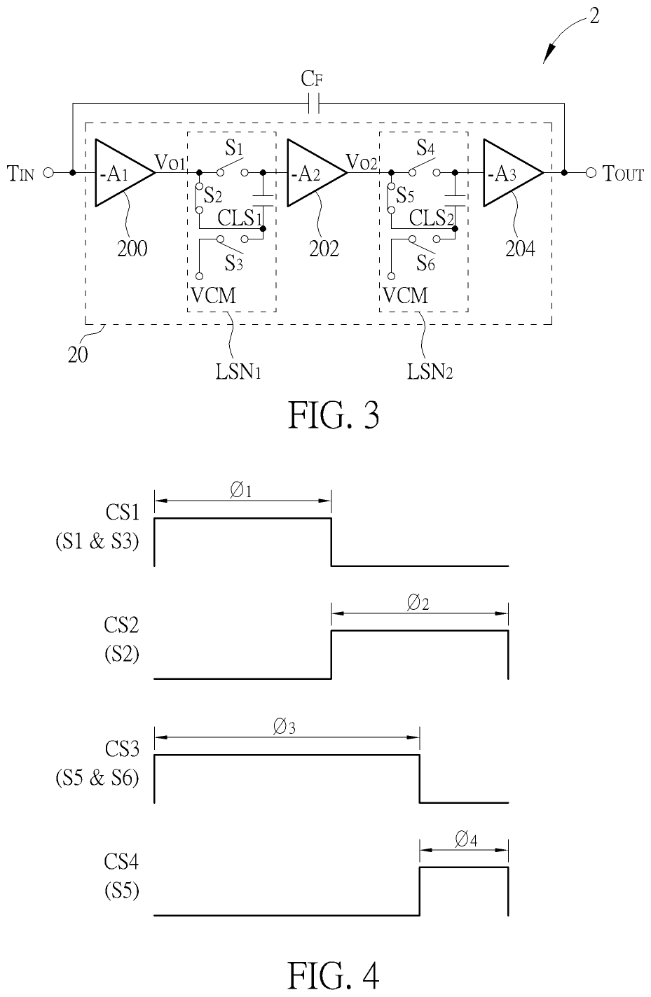

Specifically, each of the plurality of level-shifting networks includes a level-shifting capacitor and at least one switched-capacitor circuit. Please refer to FIG. 3. FIG. 3 is a schematic diagram of the level-shifting networks according to an embodiment of the present invention. As shown in FIG. 3, the level-shifting network LSN1 includes a level-shifting capacitor C_{LS1} and switches S1, S2 and S3, and the level-shifting network LSN2 includes a level-shifting capacitor C_{LS2} and switches S4, S5 and S6. The switch S1 is coupled between the output of the amplifier 200 and the input of the amplifier 202, the switch S2 is coupled between the output of the amplifier 200 and an internal node, the level-shifting capacitor C_{LS1} is coupled between the input of the amplifier 202 and the internal node, and the switch S3 is coupled between the internal node and a common mode voltage V_{CM}. Similarly, the connection of the level-shifting network LSN2 is shown in FIG. 3, which is not repeated here.

It should be noted that the level-shifting network LSN1 and the level-shifting network LSN2 are operated at different phases. Please refer to FIG. 4. FIG. 4 is a waveform diagram of control signals of the plurality of switched-capacitor circuits according to an embodiment of the present invention. For the level-shifting network LSN1, a first control signal CS1 is utilized to control the switches S1 and S3, and a second control signal CS2 complementary to the first control signal CS1 is utilized to control the switch S2. In detail, the first control signal CS1 turns on the switches S1 and S3 at a first sampling phase Ø1, so that the level-shifting network LSN1 samples a first output voltage V_{O1} of the amplifier 200. And the second control signal CS2 turns on the switch S2 at a first amplifying phase Ø2, so that the level-shifting network LSN1 shifts the level of the first output voltage V_{O1}. Similarly, for the level-shifting network LSN2, a third control signal CS3 is utilized to control the switches S4 and S6, and a fourth control signal CS4 complementary to the third control signal CS3 is utilized to control the switch S5. The third control signal CS3 turns on the switches S4 and S6 at a second sampling phase Ø3, so that the level-shifting network LSN2 samples a second output voltage V_{O2} of the amplifier 202. And the fourth control signal CS4 turns on the switch S5 at a second amplifying phase Ø4, so that the level-shifting network LSN2 shifts the level of the second output voltage V_{O2}. In detail, as shown in FIG. 4, the time the level-shifting network LSN2 shifts the level of the second output voltage V_{O2} is later than the time the level-shifting network LSN1 shifts the level of the first output voltage V_{O1}. It should be noted that, as long as the level-shifting network LSN1 and the level-shifting network LSN2 are operated at different phases, it falls within the scope of the present invention, and is not limited to the above-mentioned embodiment.

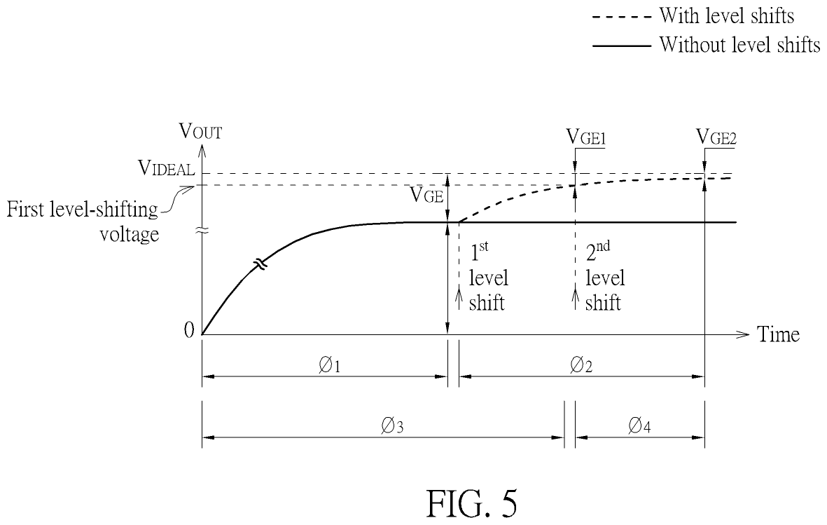

Specifically, after two level-shifting operations of the level-shifting network LSN1 and the level-shifting network LSN2, the output voltage V_{OUT} of the amplifier circuit 2 may be closer to an ideal voltage V_{IDEAL}. Please refer to FIG. 5. FIG. 5 is a waveform diagram of the output voltage V_{OUT} of the amplifier circuit 2 according to an embodiment of the present invention. As shown in FIG. 5, after the level-shifting network LSN1 shifts the level of the first output voltage V_{O1} at the first amplifying phase Ø2, the output voltage V_{OUT} is less than an ideal voltage V_{IDEAL} by a first gain error voltage V_{GE1}. And after the level-shifting network LSN2 shifts the level of the second output voltage V_{O2} at the second amplifying phase Ø4, the output voltage V_{OUT} is less than an ideal voltage V_{IDEAL} by a second gain error voltage V_{GE2}. It should be noted that the second gain error voltage V_{GE2} is smaller than the first gain error voltage V_{GE1}. And both the first gain error voltage V_{GE1} and the second gain error voltage V_{GE2} are smaller than the gain error voltage V_{GE} of the amplifier circuit 1 without the level-shifting networks. Thus, the amplifier circuit 2 may reduce the difference between the output voltage V_{OUT} and the ideal voltage V_{IDEAL}, and reduce the gain error.

In summary, in the embodiment of the present invention, the output voltage of the amplifier circuit is closer to the ideal voltage with a plurality of level-shifting operations. Therefore, the amplifier circuit may achieve a wide bandwidth and a low gain error simultaneously.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifier circuit, comprising:
an input terminal, configured to receive an input voltage;
an output terminal, configured to output an output voltage;
a multi-stage operational amplifier, coupled to the input terminal and the output terminal, and configured to amplify the input voltage to the output voltage, comprising:
a plurality of amplifiers; and
a plurality of level-shifting networks, each coupled between two of the plurality of amplifiers, configured to reduce a gain error of each output of the plurality of amplifiers; and
a feedback capacitor, coupled between the input terminal and the output terminal.

2. The amplifier circuit of claim 1, wherein a number of the plurality of amplifiers is greater than or equal to 3 and a number of the plurality of level-shifting networks is greater than or equal to 2.

3. The amplifier circuit of claim 2, wherein each of the plurality of level-shifting networks comprises a level-shifting capacitor and at least one switched-capacitor circuit operated at a sampling phase and an amplifying phase for a distributed correlated voltage level shift.

4. The amplifier circuit of claim 3, wherein the amplifying phases of the switched-capacitor circuit of the plurality of level-shifting networks are different phases.

5. An amplifier circuit, comprising:
an input terminal, configured to receive an input voltage;
an output terminal, configured to output an output voltage;
a first-stage operational amplifier, comprising a first input terminal, coupled to the input terminal, and a first output terminal, configured to amplify the input voltage to a first output voltage;
a first level-shifting network, coupled to the first output terminal, configured to shift a level of the first output voltage to a first level-shifting voltage;
a second-stage operational amplifier, comprising a second input terminal, coupled to the first level-shifting network, and a second output terminal, configured to amplify the first level-shifting voltage to a second output voltage;
a second level-shifting network, coupled to the second output terminal, configured to shift a level of the second output voltage to a second level-shifting voltage;
a third-stage operational amplifier, comprising a third input terminal, coupled to the second level-shifting network, and
a third output terminal coupled to the output terminal, configured to amplify the second level-shifting voltage to the output voltage;
a feedback capacitor, coupled between the input terminal and the output terminal.

6. The amplifier circuit of claim 5, wherein the first level-shifting network comprises a first level-shifting capacitor and at least one switch operated at a first sampling phase and a first amplifying phase to shift the level of the first output voltage, and the second level-shifting network comprises a second level-shifting capacitor and at least one switch operated at a second sampling phase and a second amplifying phase to shift the level of the second output voltage.

7. The amplifier circuit of claim 6, wherein the first amplifying phase and the second amplifying phase are different phases.
